(19) United States
(12) Patent Application Publication
(10) Pub. No.: US 2026/0031154 A1
(43) Pub. Date: Jan. 29, 2026

(54) PARTIAL BLOCK READ LEVEL DESIGN FOR A MEMORY SYSTEM

(71) Applicant: Micron Technology, Inc., Boise, ID (US)

(72) Inventors: Yu-Chung Lien, San Jose, CA (US); Murong Lang, San Jose, CA (US); Zhenming Zhou, San Jose, CA (US)

(21) Appl. No.: 19/270,298

(22) Filed: Jul. 15, 2025

Related U.S. Application Data
(60) Provisional application No. 63/675,164, filed on Jul. 24, 2024.

(51) Int. Cl. G11C 16/26; G11C 16/10; G11C 16/34

(52) U.S. Cl. CPC G11C 16/26; G11C 16/102; G11C 16/3404

(57) ABSTRACT

Methods, systems, and devices for partial block read level design for a memory system are described. The memory system may store offsets for inner word lines and outer word lines of a partial block for use in read operations. For example, the memory system may read a boundary word line of the partial block using a read voltage configured with a boundary word line offset. Alternatively, the memory system may read an inner word line of the partial block using a read voltage configured with an inner word line offset. The offsets may avoid an error limit for a read operation being exceeded even in the event of a misidentification by the memory system of an inner word line as a boundary word line, of a boundary word line as an inner word line, or both.

### CROSS REFERENCE

The present Application for Patent claims priority to U.S. Patent Application No. 63/675,164 by Lien et al., entitled “PARTIAL BLOCK READ LEVEL DESIGN FOR A MEMORY SYSTEM,” filed Jul. 24, 2024, which is assigned to the assignee hereof, and which is expressly incorporated by reference in its entirety herein.

### TECHNICAL FIELD

The following relates to one or more systems for memory, including partial block read level design for a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports partial block read level design for a memory system in accordance with examples as disclosed herein.

FIGS. 2A and 2B show examples of error diagrams that support partial block read level design for a memory system in accordance with examples as disclosed herein.

FIG. 3 shows examples of offset tables that support partial block read level design for a memory system in accordance with examples as disclosed herein.

FIG. 4 shows a block diagram of a memory system that supports partial block read level design for a memory system in accordance with examples as disclosed herein.

FIG. 5 shows a flowchart illustrating a method or methods that support partial block read level design for a memory system in accordance with examples as disclosed herein.

### DETAILED DESCRIPTION

Some memory systems may include blocks of memory cells which may be accessed via word lines coupled with the memory cells. For example, a memory system may be configured to read and write data to the memory cells based on applying a read voltage or a write voltage to the corresponding word lines. In some cases, the memory system may be configured to support partial blocks, in which one or more word lines (e.g., memory cells coupled with the one or more word lines) of a block may remain unprogrammed after a write operation. In some such cases, word lines of the partial blocks may be identified as boundary word lines or inner word lines, where a boundary word line is a last written word line (e.g., a most recently written word line) within a partial block and an inner word line is a relatively earlier written word line (e.g., not a most recently written word line). In some examples, reading data from a word line (e.g., memory cells coupled with the word line) of a partial block may include applying different read voltages (e.g., a base read voltage with different offsets) based on the word line being either a boundary word line or an inner word line. For example, to read data from a boundary word line (e.g., memory cells coupled with the boundary word line), the memory system may apply a read voltage with an offset configured for boundary word lines. Likewise, to read data from an inner word line (e.g., memory cells coupled with the inner word line), the memory system may apply the read voltage with another offset configured for inner word lines.

In some cases, word lines of a partial block may be misidentified as either a boundary word line or an inner word line in association with a read operation. For example, a boundary word line may be misidentified as an inner word line, or an inner word line may be misidentified as a boundary word line. In some memory systems, misidentifying the word line type may cause an incorrect read voltage offset to be applied to the read voltages during reading the memory cells coupled with the word lines. For example, misidentifying a boundary word line as an inner word line may cause the boundary word line to be read with a read voltage configured for inner word lines. Likewise, misidentifying an inner word line as a boundary word line may cause the inner word line to be read with a read voltage configured for boundary word lines. Reading word lines with incorrect read voltages may cause an increase in an error rate associated with performing the read operation, such that the quantity of errors may exceed a hard error limit associated with reliability and performance issues for the memory system.

In accordance with examples as described herein, a memory system may be configured to include read voltages which may be applied to the word lines to prevent errors in the event of a misidentification of the type of a word line, as well as when the type of a word line is correctly identified. For example, the memory system may store tables containing offset values for read voltages, where the offsets may be configured to prevent the hard error limit from being exceeded even if the type of a word line is misidentified and a read voltage associated with another type of word line is applied. In some cases, the tables may include improved boundary offsets associated with read voltages configured to be applied to boundary word lines, such that if an inner word line is read using an improved boundary offset, the hard error limit may not be exceeded. Additionally, or alternatively, the tables may include improved inner offsets associated with read voltages configured to be applied to inner word lines, such that if a boundary word line is read using an improved inner offset, the hard error limit may not be exceeded. In some cases, the tables may include improved offsets associated with read voltages configured to be applied to boundary word lines and inner word lines, such that if either a boundary word line or an inner word line is read using the improved offsets, the hard error limit may not be exceeded.

Thus, a “compromise” read voltage offset that will work (avoid violating an error limit) for either type of word line in a partially written block may be used for boundary word lines, for inner word lines, or both—e.g., rather than both a boundary word line voltage that only avoids the error limit for boundary word lines and a different inner word line voltage at only avoids for inner word lines, as such a wholly type-specific approach may result in errors if a word line is misclassified as being a boundary word line when it's really an inner word line, or vice versa Thus, the quantity of errors may not exceed a hard error limit even in the event of a misidentification of the type of a word line, thereby increasing reliability and performance of the memory system. among other possible benefits.

In addition to applicability in memory systems as described herein, techniques for partial block read level design for a memory system may be generally implemented to improve the performance of various electronic devices and systems (including artificial intelligence (AI) applications, augmented reality (AR) applications, virtual reality (VR) applications, automotive applications, and gaming). Some electronic device applications, including high-performance applications such as AI, AR, VR, automotive, and gaming, may be associated with relatively high processing and reliability requirements to satisfy user expectations. As such, increasing processing capabilities or reliability of the electronic devices by decreasing response times, improving power consumption, reducing complexity, reducing error rate, increasing data throughput or access speeds, decreasing communication times, or increasing memory capacity or density, among other performance indicators, may improve user experience or appeal. Implementing the techniques described herein may improve the performance of electronic devices or automotive systems by preventing word line type misidentifications during a read operation from increasing an error rate of a memory system, which may improve reliability of the electronic devices or automotive systems, among other benefits.

Features of the disclosure are illustrated and described in the context of systems, devices, and circuits. Features of the disclosure are further illustrated and described in the context of error diagrams, offset tables, and flowcharts.

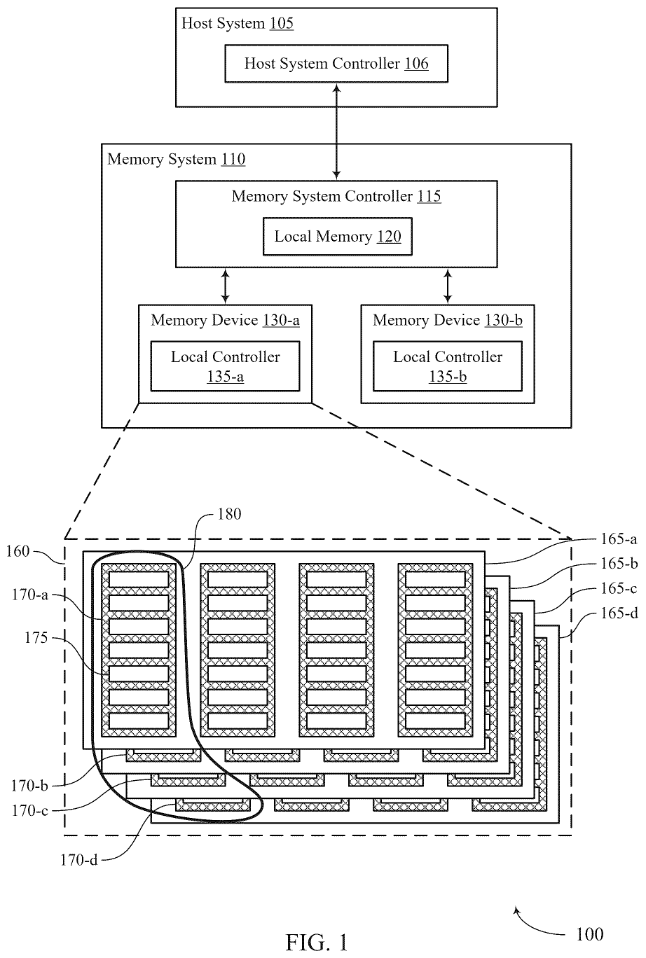

FIG. 1 shows an example of a system 100 that supports partial block read level design for a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has not been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some cases, the memory system 110 may access the blocks 170 via word lines coupled with memory cell of the blocks 170. For example, the memory system 110 may be configured to read and write data to the memory cells based on applying a read voltage or a write voltage to the corresponding word lines. In some cases, the memory system 110 may be configured to support partial blocks, in which one or more word lines (e.g., memory cells coupled with the one or more word lines) of a block 170 may remain unprogrammed after a write operation. In some such cases, word lines of the partial blocks may be identified as boundary word lines or inner word lines, where a boundary word line is a last written word line (e.g., a most recently written word line) within a partial block and an inner word line is a relatively earlier written word line (e.g., not a most recently written word line). In some examples, reading data from a word line (e.g., memory cells coupled with the word line) of a partial block may include applying different read voltages (e.g., a base read voltage with different offsets) based on the word line being either a boundary word line or an inner word line. For example, to read data from a boundary word line (e.g., memory cells coupled with the boundary word line), the memory system 110 may apply a read voltage with an offset configured for boundary word lines. Likewise, to read data from an inner word line (e.g., memory cells coupled with the inner word line), the memory system 110 may apply the read voltage with another offset configured for inner word lines.

In accordance with examples as described herein, the memory system 110 may be configured to include read voltages which may be applied to the word lines to prevent errors in case of a misidentification of the types of the word lines. For example, the memory system 110 may store tables containing offset values for read voltages, where the offsets may be configured to prevent an error limit from being exceeded if a word line is misidentified as a boundary word line (when it is really an inner word line) or an inner word line (when it really a boundary word line) and a read voltage for the wrong type of word line is applied. In some cases, the tables may include improved boundary offsets associated with read voltages configured to be applied to boundary word lines, such that if an inner word line is read using an improved boundary offset, the error limit may not be exceeded. Additionally, or alternatively, the tables may include improved inner offsets associated with read voltages configured to be applied to inner word lines, such that if a boundary word line is read using an improved inner offset, the error limit may not be exceeded. In some cases, the tables may include improved offsets associated with read voltages configured to be applied to boundary word lines and inner word lines, such that if either a boundary word line or an inner word line is read using the improved offsets, the hard error limit may not be exceeded. In some such cases, misidentifying word line types may not increase the error rate associated with performing the read operation, as an improved boundary word line offset may work for both boundary word lines and inner word lines, an improved inner word line offset may work for both inner word lines and boundary word lines, or an improved type-agnostic word line offset may work for both boundary word lines and inner word lines. Thus, the quantity of errors may not exceed the error limit even if a misidentification of word line type (e.g., a misclassification of a word line) occurs, thereby increasing reliability and performance of the memory system 110.

The system 100 may include any quantity of non-transitory computer readable media that support partial block read level design for a memory system. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

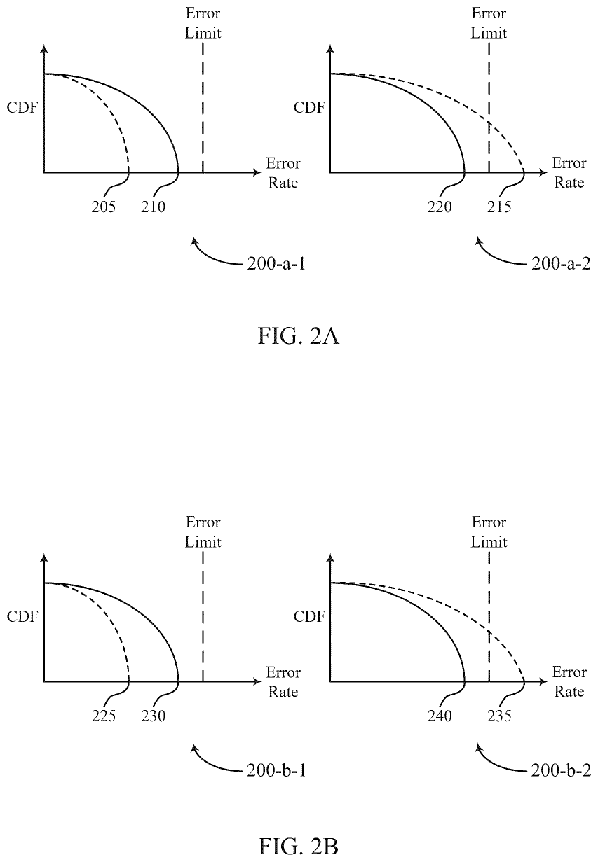

FIGS. 2A and 2B show examples of error diagrams 200 that support partial block read level design for a memory system in accordance with examples as disclosed herein. The error diagrams 200 (e.g., error diagram 200-a-1, error diagram 200-a-2, error diagram 200-b-1, and error diagram 200-b-2) may illustrate aspects or operations of a system, which may be an example of a system 100, as described with reference to FIG. 1. For example, each error diagram 200 may illustrate various error rates during read operations of a memory system, which may be an example of a memory system 110, as described with reference to FIG. 1. The memory system may be configured to implement read voltages that support improved error rates even in the event of misidentifications of word line type during read operations.

The memory system may include one or more memory arrays, where each memory array may include a quantity of blocks, which may be examples of blocks 170, as described with reference to FIG. 1. Each block may include a quantity of memory cells, which may be accessed via word lines of the one or more memory arrays. In some cases, the word lines may be access lines each coupled with one or more memory cells, such that the memory system may apply one or more voltages to a word line to facilitate access operations of the one or more memory cells coupled with the word line. For example, the memory system may be configured to write data to one or more memory cells during a write operation based on applying a write voltage to the word line coupled with the one or more memory cells. Similarly, the memory system may be configured to read data from the one or more memory cells during a read operation based on applying a read voltage to the word line.

In some cases, the memory system may support partial blocks. For example, the memory system may support writing data to a block such that the memory cells associated with one or more word lines (e.g., unprogrammed word lines) remain unprogrammed after the write operation. In some implementations, the memory system may include partial blocks based on refraining from writing to each word line of a block due to the write operation being associated with relatively less data than a capacity of data that may be stored by the memory cells of the block. In other implementations, the memory system may include partial blocks based on a start-up operation (e.g., a power transition operation from a relatively low power mode to a relatively high power mode) of the memory system. In some cases, the memory system may support identifying word lines as boundary word lines or inner word lines based on supporting partial blocks. For example, a word line may be a boundary word line based on the word line being a last written word line of a partial block. Additionally, or alternatively, a word line may be a boundary word line based on the word line having a separation from the or more unprogrammed word lines of the partial block by less than a threshold. For example, the word line may be a boundary word line if the word line is adjacent to the one or more unprogrammed word lines of the partial block. In some cases, a word line may be an inner word line based on the word line being a relatively earlier written word line of a partial block. Additionally, or alternatively, the word line may be an inner word line based on the word line having a separation from the one or more unprogrammed word lines of the partial block by more than a threshold. For example, the word line may be an inner word line if the word line is not adjacent to the one or more unprogrammed word lines of the partial block. In some such cases, whether the word line is identified as a boundary word line or an inner word line may be based on a position of the word line within the partial block compared to the one or more unprogrammed word lines. For example, the memory system may write data using a first word line, then the memory system may write data using a second word line, however the memory system may refrain from writing data using a third word line. In such an example, the first word line is an inner word line, the second word line is a boundary word line, and the third word line is an unprogrammed word line.

In some cases, the memory system may apply different read voltages to a word line of a partial block based on whether the word line is boundary word line or an inner word line. For example, the memory system may be configured to identify that the word line is a boundary word line, and the memory system may apply a read voltage associated with (e.g., configured for) boundary word lines to the word line during a read operation. Alternatively, the memory system may be configured to identify that the word line is an inner word line, and the memory system may apply a read voltage associated with (e.g., configured for) inner word lines to the word line during a read operation. In some such examples, the memory system may implement a base read voltage with different offsets to support the different read voltages. For example, a read voltage associated with boundary word lines may include an offset (e.g., a boundary offset, a boundary word line offset) configured for boundary word lines. Likewise, a read voltage associated with inner word lines may include an offset (e.g., an inner offset, an inner word line offset) configured for inner word lines.

Implementing a read voltage associated with boundary word lines for boundary word lines and a read voltage associated with inner word lines for inner word lines may prevent errors during such read operations. For example, using a boundary word line offset for boundary word lines and an inner word line offset for inner word lines may prevent an error rate or a quantity of errors produced during the read operations from satisfying an error limit (e.g., a hard error limit). In some implementations, the error limit may be associated with a reliability (e.g., an allowed quantity of errors) of the memory system. In some such implementations, the error limit may be adjusted based on user or contextual demands (e.g., based on a general product category implementing the memory system) regarding reliability of the memory system.

In some cases, the memory system may misidentify a word line of a partial block as a boundary word line or an inner word line. For example, if the memory system has identified a first word line as a boundary word line, and other word lines are programmed to the same partial block at a later time without the memory system reidentifying the new boundary line, the memory system may misidentify the word line as a boundary word line rather than an inner word line. Or, the memory system may misidentify an inner word line as a boundary word line based on misidentifying that the word line has a separation from the one or more unprogrammed word lines of the partial block less than a threshold even through the separation is actually greater than the threshold. Conversely, the memory system may misidentify a boundary word line as an inner word line based on misidentifying that the word line has a separation from the one or more unprogrammed word lines of the partial block greater than a threshold even through the separation is actually less than the threshold. In some such cases, misidentifying a word line may cause a read voltage configured for a different type of word line to mistakenly be applied to the word line. For example, if an inner word line is misidentified as a boundary word line, and a standard boundary word line offset is used in the read voltage for the inner word line, the read operation may exceed the error limit. Alternatively, if a boundary word line is misidentified as an inner word line, and a standard inner word line offset is used in the read voltage for the boundary word line, the read operation may exceed the error limit.

However, in accordance with examples as described herein, the memory system may implement improved offsets for the read voltages applied to different word lines. That is, the memory system may implement offsets configured to avoid causing the read operations to exceed the error limit even in the event of a misidentification of whether a particular word line is a boundary word line or an inner word line.

For example, the memory system may implement improved boundary word line offsets and inner word line offsets, such that if a word line is misidentified, the improved boundary word line offsets and inner word line offsets may not cause the read operation for the word line to exceed the error limit. In some examples, the memory system may misidentify an inner word line as a boundary word line, and an improved boundary word line offset may be used to read the inner word line. However, because the improved boundary word line offset is configured to avoid errors even when used by the memory system to read an inner word line, reading the inner word line using the improved boundary word line offset may not cause the read operation to exceed the error limit. Or, the memory system may misidentify a boundary word line as an inner word line, and an improved inner word line offset may be used to read the boundary word line. However, because the improved boundary word line offset is configured to avoid errors even when used by the memory system to read a boundary word line, reading the boundary word line using the improved inner word line offset may not cause the read operation to exceed the error limit.

FIGS. 2A and 2B illustrate read operations on word lines of the memory system using standard offsets and the improved offsets as described herein. For example, FIG. 2A includes error diagrams 200-a-1 and 200-a-2, which each illustrate read operations on word lines using a standard boundary word line offset and an improved boundary word line offset. The error diagrams 200-a-1 and 200-a-2 illustrate a relationship between a cumulative distribution function of the offsets and an error rate of read operations implementing the offsets. For example, the error diagram 200-a-1 illustrates an error rate of a cumulative distribution function 205 associated with using standard boundary word line offsets for reading a boundary word line. Likewise, the error diagram 200-a-1 illustrates an error rate of a cumulative distribution function 210 associated with using the improved boundary word line offsets for reading a boundary word line. Additionally, the error diagram 200-a-2 illustrates an error rate of a cumulative distribution function 215 associated with using standard boundary word line offsets for reading an inner word line. Likewise, the error diagram 200-a-2 illustrates an error rate of a cumulative distribution function 220 associated with using the improved boundary word line offsets for reading an inner word line.

As illustrated in the error diagram 200-a-1, implementing the improved boundary word line offsets for reading a boundary word line may increase an error rate of the read operation as compared to implementing the standard boundary word line offsets. However, implementing the improved boundary word line offsets for read a boundary word line may not increase an error rate of the read operation to exceed the error limit. As illustrated in the error diagram 200-a-2, implementing the improved boundary word line offsets for reading an inner word line may decrease an error rate of the read operation as compared to implementing the standard boundary word line offsets. That is, implementing the standard boundary word line offsets may cause an error rate of the read operation to exceed the error limit, yet implementing the improved boundary word line offsets may not cause the error rate of the read operation to exceed the error limit. Thus, the improved boundary word line offsets may support reading inner word lines using boundary word line offsets without exceeding the error limit. However, if the improved boundary word line offsets are used in conjunction with standard inner word line offsets, it may not be guaranteed that reading boundary word lines using the standard inner word line offsets will not exceed the error limit.

FIG. 2B includes error diagrams 200-b-1 and 200-b-2, which each illustrate read operations on word lines using a standard inner word line offset and an improved inner word line offset. The error diagrams 200-b-1 and 200-b-2 illustrate a relationship between a cumulative distribution function of the offsets and an error rate of read operations implementing the offsets. For example, the error diagram 200-b-1 illustrates an error rate of a cumulative distribution function 225 associated with using standard inner word line offsets for reading an inner word line. Likewise, the error diagram 200-b-1 illustrates an error rate of a cumulative distribution function 230 associated with using the improved inner word line offsets for reading an inner word line. Additionally, the error diagram 200-b-2 illustrates an error rate of a cumulative distribution function 235 associated with using standard inner word line offsets for reading a boundary word line. Likewise, the error diagram 200-b-2 illustrates an error rate of a cumulative distribution function 240 associated with using the improved inner word line offsets for reading a boundary word line.

As illustrated in the error diagram 200-b-1, implementing the improved inner word line offsets for reading an inner word line may increase an error rate of the read operation as compared to implementing the standard inner word line offsets. However, implementing the improved inner word line offsets for read an inner word line may not increase an error rate of the read operation to exceed the error limit. As illustrated in the error diagram 200-b-2, implementing the improved inner word line offsets for reading a boundary word line may decrease an error rate of the read operation as compared to implementing the standard inner word line offsets. That is, implementing the standard inner word line offsets may cause an error rate of the read operation to exceed the error limit, yet implementing the improved inner word line offsets may not cause the error rate of the read operation to exceed the error limit. Thus, the improved inner word line offsets may support reading boundary word lines using inner word line offsets without exceeding the error limit. However, if the improved inner word line offsets are used in conjunction with standard boundary word line offsets, it may not be guaranteed that reading inner word lines using the standard boundary word line offsets will not exceed the error limit.

Implementing the improved offsets may support improved reliability of the memory system by preventing error rates of read operations from exceeding the error limit. For example, implementing the improved boundary word line offsets may enable misidentified inner word lines from being read with an error rate exceeding the error limit. Likewise, implementing the improved inner word line offsets may enable misidentified boundary word lines from being read with an error rate exceeding the error limit. Thus, implementing the improved offsets may decrease a likelihood in which a misidentification of a word line increases an error rate of the memory system above a reliability threshold.

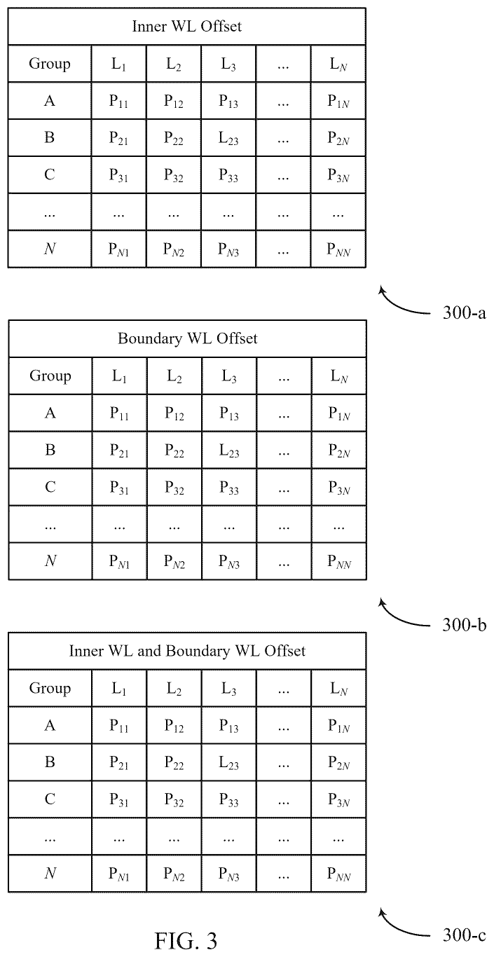

FIG. 3 shows examples of offset tables 300 that support partial block read level design for a memory system in accordance with examples as disclosed herein. The offset tables 300 (e.g., offset table 300-a, offset table 300-b, offset table 300-c) may illustrate aspects or operations of a system, which may be an example of a system 100, as described with reference to FIG. 1. For example, the offset tables 300 may be implemented within a memory system, which may be an example of a memory system 110, as described with reference to FIG. 1. Additionally, the offset tables 300 may be implemented by the memory system to support the error diagrams 200, as described with reference to FIGS. 2A and 2B. The offset tables 300 may illustrate the improved offsets as described herein, which may avoid an error limit for a read operation being exceeded even in the event of a misidentification by the memory system of an inner word line as a boundary word line, of a boundary word line as an inner word line, or both.

The offset tables 300 may illustrate inner word line offsets (e.g., offsets configured for inner word lines, which may be examples of improved inner word line offsets that also avoid errors when used for boundary word lines), boundary word line offsets (e.g., offsets configured for boundary word lines, which may be examples of improved boundary word line offsets that also avoid errors when used for inner word lines), and hybrid word line offsets (e.g., offsets configured to be used for both inner word lines or boundary word lines, which may avoid errors when used for either type of word line). For example, the offset table 300-a illustrates inner word line offsets, the offset table 300-b illustrates boundary word line offsets, and the offset table 300-c illustrates hybrid word line offsets. Each offset may be illustrated by a variable P, which may be indicative of a voltage offset applied to a base read voltage. In some cases, each variable P may represent a negative voltage offset, such that applying the negative voltage offset may reduce the base read voltage applied to the respective word line during a read operation.

The offset tables 300 may each be organized by levels (e.g., levels L1, L2, L3, . . . , Lx) of the word lines within one or more memory arrays of the memory system. Additionally, the offset tables 300 may each be organized by groups (e.g., groups A, B, C, . . . , N) of word lines, where each group may be associated with a range of word lines. In some examples, the offset tables 300 may be associated with a respective memory array, and each group may be associated with a respective subrange of word lines from the range of word lines associated with the memory array. For example, each group may correspond to a range of last written word lines (e.g., LWWL column), such that if a last written word line for a partial block is within a group, the offset may be determined by identifying said group. Thus, to determine an offset of a word line, the memory system may identify whether the word line is an inner word line or a boundary word line, then identify the group and level associated with the word line. For example, if the word line is an inner word line within Group A, and the word line is located in level 1 (e.g., L1), the inner word line offset according to offset table 300-a may be P₁₁.

In some cases, the memory system may implement standard word line offsets, improved word line offsets (e.g., which avoid an error limit for a read operation being exceeded even in the event of a misidentification by the memory system regarding whether a word line is an inner word line or a boundary word line, as described herein), or any combination thereof.

For example, in a first case, the memory system may implement standard inner word line offsets and improved boundary word line offsets. That is, the improved boundary word line offsets may support reading inner word lines using the boundary word line offsets without causing the read operations to exceed the error limit. However, if boundary word lines are read using the standard inner word line offsets, the standard inner word line offsets may not be guaranteed to avoid causing the read operations to exceed the error limit.

In some examples, an improved boundary word line offset may be determined (e.g., calculated) based on a combination of a standard boundary word line offset (which may be configured to avoid violation of an error limit when used to read memory cells coupled with a boundary word line but not specifically configured—e.g., not guaranteed to avoid violation of the error limit-when used to read memory cells coupled with an inner word line) and a standard inner word line offset (which may be configured to avoid violation of an error limit when used to read memory cells coupled with an inner word line but not specifically configured—e.g., not guaranteed to avoid violation of the error limit-when used to read memory cells coupled with a boundary word line). For example, an improved boundary word line offset may be determined as an average, a median value, or other blended or interim value based on a corresponding standard boundary word line offset and a corresponding standard inner word line offset, where the corresponding standard boundary word line offset and the corresponding standard inner word line offset may correspond to a same word line group and word line level combination.

In a second case, the memory system may implement improved inner word line offsets and standard boundary word line offsets. That is, the improved inner word line offsets may support reading boundary word lines using the inner word line offsets without causing the read operations to exceed the error limit. However, if inner word lines are read using the standard boundary word line offsets, the standard boundary word line offsets may not be guaranteed to avoid causing the read operations to exceed the error limit.

In some examples, an improved inner word line offset may be determined (e.g., calculated) based on a combination of a standard inner word line offset (which may be configured to avoid violation of an error limit when used to read memory cells coupled with an inner word line but not specifically configured—e.g., not guaranteed to avoid violation of the error limit-when used to read memory cells coupled with a boundary word line) and a standard boundary word line offset (which may be configured to avoid violation of an error limit when used to read memory cells coupled with a boundary word line but not specifically configured—e.g., not guaranteed to avoid violation of the error limit-when used to read memory cells coupled with an inner word line). For example, an improved inner word line offset may be determined as an average, a median value, or other blended or interim value based on a corresponding standard inner word line offset and a corresponding standard boundary word line offset, where the corresponding standard inner word line offset and the corresponding standard boundary word line offset may correspond to a same word line group and word line level combination.

In a third case, the memory system may implement improved hybrid word line offsets. That is, the offsets illustrated in the offset table 300-c may be used for either inner word lines or boundary word lines. For example, the offsets illustrated in the offset table 300-c may support reading boundary word lines or inner word lines using the inner word line and boundary word line offsets without causing the read operations to exceed the error limit.

In some examples, an improved hybrid word line offset may be determined (e.g., calculated) based on a combination of a standard boundary word line offset (which may be configured to avoid violation of an error limit when used to read memory cells coupled with a boundary word line but not specifically configured—e.g., not guaranteed to avoid violation of the error limit-when used to read memory cells coupled with an inner word line) and a standard inner word line offset (which may be configured to avoid violation of an error limit when used to read memory cells coupled with an inner word line but not specifically configured—e.g., not guaranteed to avoid violation of the error limit-when used to read memory cells coupled with a boundary word line). For example, an improved hybrid word line offset may be determined as an average, a median value, or other blended or interim value based on a corresponding standard boundary word line offset and a corresponding standard inner word line offset, where the corresponding standard boundary word line offset and the corresponding standard inner word line offset may correspond to a same word line group and word line level combination.

The memory system may store the offset table 300-a, the offset table 300-b, the offset table 300-c, or any combination thereof to support performing read operations of partial blocks. In some examples, the memory system may store a first offset table (e.g., offset table 300-a) of improved inner word line offsets (to be used when a word line to be read is identified as an inner word line) and a second offset table of standard boundary word line offsets (to be used when a word line to be read is identified as a boundary word line). And in some examples, the memory system may store a first offset table (e.g., offset table 300-b) of improved boundary word line offsets (to be used when a word line to be read is identified as a boundary word line) and a second offset table of standard inner word line offsets (to be used when a word line to be read is identified as an inner word line). And, in some examples, the memory system may store an offset table (e.g., offset table 300-c) of improved hybrid word line offsets (to be used when a word line to be read is identified as a boundary word line or as an inner word line, or to allow the memory system to refrain from identifying whether a word line is a boundary word line or inner word line, the choice of which hybrid word line offset to use may not depend on whether a word line is a boundary word line or inner word line).

The memory system may store the improved offsets in a controller of the memory system (e.g., a memory system controller 115, as described with reference to FIG. 1), such that the controller may select offsets for read operations from the stored improved offsets. For example, the controller may receive a read command from a host system (e.g., a host system 105, as described with reference to FIG. 1) coupled with the memory system, and the controller may identify one or more word lines associated with the read command. Then, the controller may determine whether the one or more word lines are inner word lines, boundary word lines, or a combination thereof, and the controller may select the appropriate offsets for the read voltages to be applied to the one or more word lines from the stored offset table. After selecting the appropriate offsets, the controller may apply the read voltages to the one or more word lines based on the selected offsets. In some cases, the controller may sense the data from the memory cells coupled with the one or more word lines based on comparing the voltages of the one or more word lines with reference voltages. After sensing the data, the controller may transmit the data to the host system to complete the read operation.

Implementing the improved offsets from the offset tables 300-a, 300-b, and 300-c may improve reliability of the memory system by preventing error rates of read operations from exceeding the error limit. For example, implementing the improved boundary word line offsets may enable misidentified inner word lines from being read with an error rate exceeding the error limit. Likewise, implementing the improved inner word line offsets may enable misidentified boundary word lines from being read with an error rate exceeding the error limit. Thus, implementing the improved offsets may decrease a likelihood in which a misidentification of a word line increases an error rate of the memory system above a reliability threshold.

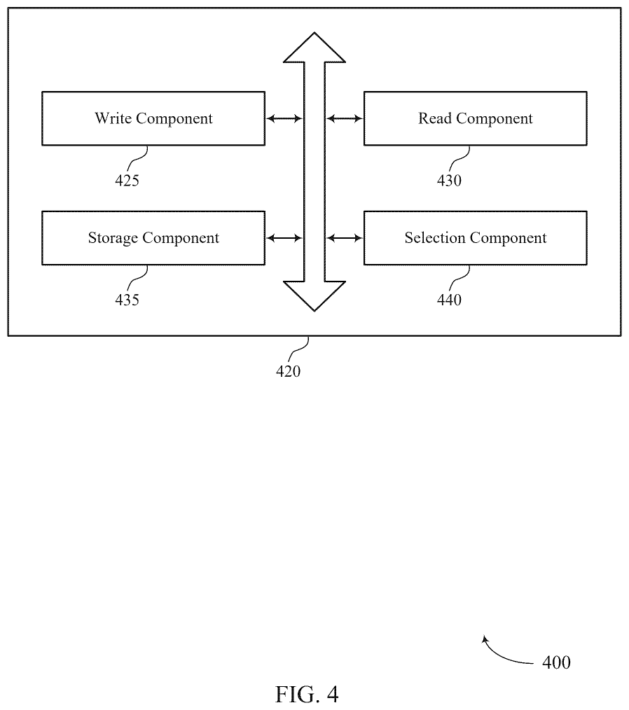

FIG. 4 shows a block diagram 400 of a memory system 420 that supports partial block read level design for a memory system in accordance with examples as disclosed herein. The memory system 420 may be an example of aspects of a memory system as described with reference to FIGS. 1 through 3. The memory system 420, or various components thereof, may be an example of means for performing various aspects of partial block read level design for a memory system as described herein. For example, the memory system 420 may include a write component 425, a read component 430, a storage component 435, a selection component 440, or any combination thereof. Each of these components, or components of subcomponents thereof (e.g., one or more processors, one or more memories), may communicate, directly or indirectly, with one another (e.g., via one or more buses).

The write component 425 may be configured as or otherwise support a means for writing first data to a first set of one or more word lines within a block of a memory array, where the block of the memory array includes one or more unprogrammed word lines after writing the first data, each of the one or more unprogrammed word lines including a word line coupled with unprogrammed memory cells. The read component 430 may be configured as or otherwise support a means for reading, after writing the first data, second data from a first word line of the first set of one or more word lines using a read voltage that is based at least in part on an offset value, where the offset value is configured to satisfy an error limit associated with reading the second data both when a separation between the first word line and the one or more unprogrammed word lines is smaller than or equal to a threshold and when the separation between the first word line and the one or more unprogrammed word lines is larger than the threshold.

In some examples, the separation between the first word line and the one or more unprogrammed word lines is smaller than or equal to the threshold, and the read component 430 may be configured as or otherwise support a means for reading third data from a second word line of the first set of one or more word lines using a second read voltage that is different than the read voltage, where a separation between the second word line and the one or more unprogrammed word lines is larger than the threshold, and where the second read voltage is based at least in part on a second offset value that is configured to satisfy the error limit when the separation between the second word line and the one or more unprogrammed word lines is larger than the threshold.

In some examples, the second offset value is not guaranteed to (e.g., not specifically configured to) satisfy the error limit when the separation between the second word line and the one or more unprogrammed word lines is smaller than or equal to the threshold.

In some examples, the separation between the first word line and the one or more unprogrammed word lines is larger than the threshold, and the read component 430 may be configured as or otherwise support a means for reading fourth data from a third word line of the first set of one or more word lines using a third read voltage that is different than the read voltage, where a separation between the third word line and the one or more unprogrammed word lines is smaller than or equal to the threshold, and where the third read voltage is based at least in part on a third offset value that is configured to satisfy the error limit when the separation between the third word line and the one or more unprogrammed word lines is smaller than or equal to the threshold.

In some examples, the third offset value is not guaranteed to (e.g., not specifically configured to) satisfy the error limit when the separation between the third word line and the one or more unprogrammed word lines is larger than the threshold.

In some examples, the storage component 435 may be configured as or otherwise support a means for storing, at the memory system, a first table of offset values and a second table of offset values, where: the first table includes a first plurality of offset values each associated with the separation between the first word line the one or more unprogrammed word lines being smaller than or equal to the threshold, and the second table includes a second plurality of offset values each associated with the separation between the first word line the one or more unprogrammed word lines being larger than the threshold. In some examples, the selection component 440 may be configured as or otherwise support a means for selecting the offset value from the first plurality of offset values or from the second plurality of offset values, where whether the offset value is selected from the first plurality of offset values or is selected from the second plurality of offset values is based at least in part on whether the separation between the first word line and the one or more unprogrammed word lines is larger than the threshold.

In some examples, each of the first plurality of offset values is configured to satisfy the error limit when the separation between the first word line and the one or more unprogrammed word lines is larger than the threshold; and each of the second plurality of offset values is not guaranteed to satisfy the error limit when the separation between the first word line and the one or more unprogrammed word lines is smaller than or equal the threshold.

In some examples, each of the first plurality of offset values is not guaranteed to satisfy the error limit when the separation between the first word line and the one or more unprogrammed word lines is larger than the threshold; and each of the second plurality of offset values is configured to satisfy the error limit when the separation between the first word line and the one or more unprogrammed word lines is smaller than or equal the threshold.

In some examples, the storage component 435 may be configured as or otherwise support a means for storing, at the memory system, a table including a plurality of offset values that are each configured to satisfy the error limit associated with reading the second data both when a separation between the first word line and the one or more unprogrammed word lines is smaller than or equal to a threshold and when the separation between the first word line and the one or more unprogrammed word lines is larger than the threshold. In some examples, the selection component 440 may be configured as or otherwise support a means for selecting the offset value from the plurality of offset values.

In some examples, the offset value is based at least in part on a position of a most recently written word line within the block.

In some examples, the separation between the first word line and the one or more unprogrammed word lines being smaller than or equal to the threshold includes the first word line being adjacent to an unprogrammed word line; and the separation between the first word line and the one or more unprogrammed word lines being larger than the threshold includes the first word line not being adjacent to any unprogrammed word line.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

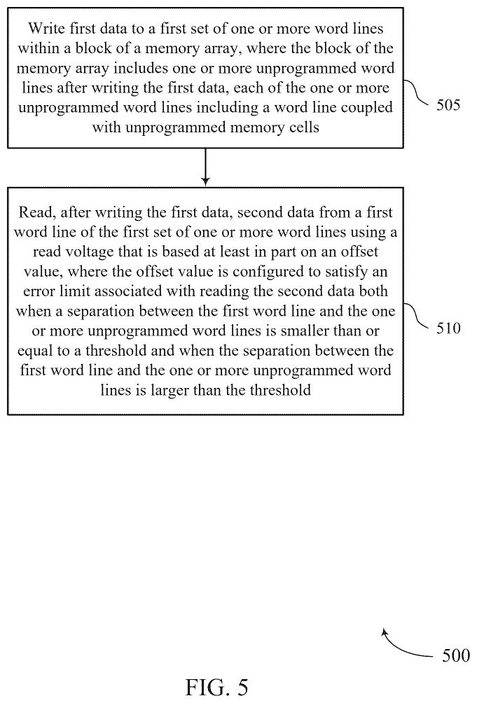

FIG. 5 shows a flowchart illustrating a method 500 that supports partial block read level design for a memory system in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include writing first data to a first set of one or more word lines within a block of a memory array, where the block of the memory array includes one or more unprogrammed word lines after writing the first data, each of the one or more unprogrammed word lines including a word line coupled with unprogrammed memory cells. In some examples, aspects of the operations of 505 may be performed by a write component 425 as described with reference to FIG. 4.

At 510, the method may include reading, after writing the first data, second data from a first word line of the first set of one or more word lines using a read voltage that is based at least in part on an offset value, where the offset value is configured to satisfy an error limit associated with reading the second data both when a separation between the first word line and the one or more unprogrammed word lines is smaller than or equal to a threshold and when the separation between the first word line and the one or more unprogrammed word lines is larger than the threshold. In some examples, aspects of the operations of 510 may be performed by a read component 430 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for writing first data to a first set of one or more word lines within a block of a memory array, where the block of the memory array includes one or more unprogrammed word lines after writing the first data, each of the one or more unprogrammed word lines including a word line coupled with unprogrammed memory cells and reading, after writing the first data, second data from a first word line of the first set of one or more word lines using a read voltage that is based at least in part on an offset value, where the offset value is configured to satisfy an error limit associated with reading the second data both when a separation between the first word line and the one or more unprogrammed word lines is smaller than or equal to a threshold and when the separation between the first word line and the one or more unprogrammed word lines is larger than the threshold.

Aspect 2: The method, apparatus, or non-transitory computer-readable medium of aspect 1, where the separation between the first word line and the one or more unprogrammed word lines is smaller than or equal to the threshold, and where the method, apparatuses, and non-transitory computer-readable medium further includes operations, features, circuitry, logic, means, or instructions, or any combination thereof for reading third data from a second word line of the first set of one or more word lines using a second read voltage that is different than the read voltage, where a separation between the second word line and the one or more unprogrammed word lines is larger than the threshold, and where the second read voltage is based at least in part on a second offset value that is configured to satisfy the error limit when the separation between the second word line and the one or more unprogrammed word lines is larger than the threshold.

Aspect 3: The method, apparatus, or non-transitory computer-readable medium of aspect 2, where the second offset value is not guaranteed to satisfy the error limit when the separation between the second word line and the one or more unprogrammed word lines is smaller than or equal to the threshold.

Aspect 4: The method, apparatus, or non-transitory computer-readable medium of any of aspects 1 through 3, where the separation between the first word line and the one or more unprogrammed word lines is larger than the threshold, and where the method, apparatuses, and non-transitory computer-readable medium further includes operations, features, circuitry, logic, means, or instructions, or any combination thereof for reading fourth data from a third word line of the first set of one or more word lines using a third read voltage that is different than the read voltage, where a separation between the third word line and the one or more unprogrammed word lines is smaller than or equal to the threshold, and where the third read voltage is based at least in part on a third offset value that is configured to satisfy the error limit when the separation between the third word line and the one or more unprogrammed word lines is smaller than or equal to the threshold.

Aspect 5: The method, apparatus, or non-transitory computer-readable medium of aspect 4, where the third offset value is not guaranteed to satisfy the error limit when the separation between the third word line and the one or more unprogrammed word lines is larger than the threshold.

Aspect 6: The method, apparatus, or non-transitory computer-readable medium of any of aspects 1 through 5, further including operations, features, circuitry, logic, means, or instructions, or any combination thereof for storing, at the memory system, a first table of offset values and a second table of offset values, where: the first table includes a first plurality of offset values each associated with the separation between the first word line the one or more unprogrammed word lines being smaller than or equal to the threshold, and the second table includes a second plurality of offset values each associated with the separation between the first word line the one or more unprogrammed word lines being larger than the threshold; and selecting the offset value from the first plurality of offset values or from the second plurality of offset values, where whether the offset value is selected from the first plurality of offset values or is selected from the second plurality of offset values is based at least in part on whether the separation between the first word line and the one or more unprogrammed word lines is larger than the threshold.

Aspect 7: The method, apparatus, or non-transitory computer-readable medium of aspect 6, where each of the first plurality of offset values is configured to satisfy the error limit when the separation between the first word line and the one or more unprogrammed word lines is larger than the threshold; and where each of the second plurality of offset values is not guaranteed to satisfy the error limit when the separation between the first word line and the one or more unprogrammed word lines is smaller than or equal the threshold.

Aspect 8: The method, apparatus, or non-transitory computer-readable medium of any of aspects 6 through 7, where each of the first plurality of offset values is not guaranteed to satisfy the error limit when the separation between the first word line and the one or more unprogrammed word lines is larger than the threshold; and where each of the second plurality of offset values is configured to satisfy the error limit when the separation between the first word line and the one or more unprogrammed word lines is smaller than or equal the threshold.

Aspect 9: The method, apparatus, or non-transitory computer-readable medium of any of aspects 1 through 8, further including operations, features, circuitry, logic, means, or instructions, or any combination thereof for storing, at the memory system, a table including a plurality of offset values that are each configured to satisfy the error limit associated with reading the second data both when a separation between the first word line and the one or more unprogrammed word lines is smaller than or equal to a threshold and when the separation between the first word line and the one or more unprogrammed word lines is larger than the threshold and selecting the offset value from the plurality of offset values.

Aspect 10: The method, apparatus, or non-transitory computer-readable medium of any of aspects 1 through 9, where the offset value is based at least in part on a position of a most recently written word line within the block.

Aspect 11: The method, apparatus, or non-transitory computer-readable medium of any of aspects 1 through 10, where the separation between the first word line and the one or more unprogrammed word lines being smaller than or equal to the threshold includes the first word line being adjacent to an unprogrammed word line; and where the separation between the first word line and the one or more unprogrammed word lines being larger than the threshold includes the first word line not being adjacent to any unprogrammed word line.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
write first data to a first set of one or more word lines within a block of a memory array, wherein the block of the memory array comprises one or more unprogrammed word lines after writing the first data, each of the one or more unprogrammed word lines comprising a word line coupled with unprogrammed memory cells; and
read, after writing the first data, second data from a first word line of the first set of one or more word lines using a read voltage that is based at least in part on an offset value, wherein the offset value is configured to satisfy an error limit associated with reading the second data both when a separation between the first word line and the one or more unprogrammed word lines is smaller than or equal to a threshold and when the separation between the first word line and the one or more unprogrammed word lines is larger than the threshold.

2. The memory system of claim 1, wherein the separation between the first word line and the one or more unprogrammed word lines is smaller than or equal to the threshold, and wherein the processing circuitry is further configured to cause the memory system to:
read third data from a second word line of the first set of one or more word lines using a second read voltage that is different than the read voltage, wherein a separation between the second word line and the one or more unprogrammed word lines is larger than the threshold, and wherein the second read voltage is based at least in part on a second offset value that is configured to satisfy the error limit when the separation between the second word line and the one or more unprogrammed word lines is larger than the threshold.

3. The memory system of claim 2, wherein the second offset value is not guaranteed to satisfy the error limit when the separation between the second word line and the one or more unprogrammed word lines is smaller than or equal to the threshold.

4. The memory system of claim 1, wherein the separation between the first word line and the one or more unprogrammed word lines is larger than the threshold, and wherein the processing circuitry is further configured to cause the memory system to:
read fourth data from a third word line of the first set of one or more word lines using a third read voltage that is different than the read voltage, wherein a separation between the third word line and the one or more unprogrammed word lines is smaller than or equal to the threshold, and wherein the third read voltage is based at least in part on a third offset value that is configured to satisfy the error limit when the separation between the third word line and the one or more unprogrammed word lines is smaller than or equal to the threshold.

5. The memory system of claim 4, wherein the third offset value is not guaranteed to satisfy the error limit when the separation between the third word line and the one or more unprogrammed word lines is larger than the threshold.

6. The memory system of claim 1, wherein the processing circuitry is further configured to cause the memory system to:
store, at the memory system, a first table of offset values and a second table of offset values, wherein:
the first table comprises a first plurality of offset values each associated with the separation between the first word line the one or more unprogrammed word lines being smaller than or equal to the threshold, and
the second table comprises a second plurality of offset values each associated with the separation between the first word line the one or more unprogrammed word lines being larger than the threshold; and
select the offset value from the first plurality of offset values or from the second plurality of offset values, wherein whether the offset value is selected from the first plurality of offset values or is selected from the second plurality of offset values is based at least in part on whether the separation between the first word line and the one or more unprogrammed word lines is larger than the threshold.

7. The memory system of claim 6, wherein:
each of the first plurality of offset values is configured to satisfy the error limit when the separation between the first word line and the one or more unprogrammed word lines is larger than the threshold; and
each of the second plurality of offset values is not guaranteed to satisfy the error limit when the separation between the first word line and the one or more unprogrammed word lines is smaller than or equal the threshold.

8. The memory system of claim 6, wherein:
each of the first plurality of offset values is not guaranteed to satisfy the error limit when the separation between the first word line and the one or more unprogrammed word lines is larger than the threshold; and
each of the second plurality of offset values is configured to satisfy the error limit when the separation between the first word line and the one or more unprogrammed word lines is smaller than or equal the threshold.

9. The memory system of claim 1, wherein the processing circuitry is further configured to cause the memory system to:
store, at the memory system, a table comprising a plurality of offset values that are each configured to satisfy the error limit associated with reading the second data both when a separation between the first word line and the one or more unprogrammed word lines is smaller than or equal to a threshold and when the separation between the first word line and the one or more unprogrammed word lines is larger than the threshold; and
select the offset value from the plurality of offset values.

10. The memory system of claim 1, wherein the offset value is based at least in part on a position of a most recently written word line within the block.

11. The memory system of claim 1, wherein:
the separation between the first word line and the one or more unprogrammed word lines being smaller than or equal to the threshold comprises the first word line being adjacent to an unprogrammed word line; and
the separation between the first word line and the one or more unprogrammed word lines being larger than the threshold comprises the first word line not being adjacent to any unprogrammed word line.

12. A non-transitory computer-readable medium storing code, the code comprising instructions executable by one or more processors to:
write first data to a first set of one or more word lines within a block of a memory system, wherein the block of the memory system comprises one or more unprogrammed word lines after writing the first data, each of the one or more unprogrammed word lines comprising a word line coupled with unprogrammed memory cells; and
read, after writing the first data, second data from a first word line of the first set of one or more word lines using a read voltage that is based at least in part on an offset value, wherein the offset value is configured to satisfy an error limit associated with reading the second data both when a separation between the first word line and the one or more unprogrammed word lines is smaller than or equal to a threshold and when the separation between the first word line and the one or more unprogrammed word lines is larger than the threshold.

13. The non-transitory computer-readable medium of claim 12, wherein the separation between the first word line and the one or more unprogrammed word lines is smaller than or equal to the threshold, and wherein the instructions are further executable by the one or more processors to:
read third data from a second word line of the first set of one or more word lines using a second read voltage that is different than the read voltage, wherein a separation between the second word line and the one or more unprogrammed word lines is larger than the threshold, and wherein the second read voltage is based at least in part on a second offset value that is configured to satisfy the error limit when the separation between the second word line and the one or more unprogrammed word lines is larger than the threshold.

14. The non-transitory computer-readable medium of claim 12, wherein the separation between the first word line and the one or more unprogrammed word lines is larger than the threshold, and wherein the instructions are further executable by the one or more processors to:
read fourth data from a third word line of the first set of one or more word lines using a third read voltage that is different than the read voltage, wherein a separation between the third word line and the one or more unprogrammed word lines is smaller than or equal to the threshold, and wherein the third read voltage is based at least in part on a third offset value that is configured to satisfy the error limit when the separation between the third word line and the one or more unprogrammed word lines is smaller than or equal to the threshold.

15. The non-transitory computer-readable medium of claim 12, wherein the instructions are further executable by the one or more processors to:
store, at the memory system, a first table of offset values and a second table of offset values, wherein:
the first table comprises a first plurality of offset values each associated with the separation between the first word line the one or more unprogrammed word lines being smaller than or equal to the threshold, and
the second table comprises a second plurality of offset values each associated with the separation between the first word line the one or more unprogrammed word lines being larger than the threshold; and
select the offset value from the first plurality of offset values or from the second plurality of offset values, wherein whether the offset value is selected from the first plurality of offset values or is selected from the second plurality of offset values is based at least in part on whether the separation between the first word line and the one or more unprogrammed word lines is larger than the threshold.

16. The non-transitory computer-readable medium of claim 15, wherein:
each of the first plurality of offset values is configured to satisfy the error limit when the separation between the first word line and the one or more unprogrammed word lines is larger than the threshold; and
each of the second plurality of offset values is not guaranteed to satisfy the error limit when the separation between the first word line and the one or more unprogrammed word lines is smaller than or equal the threshold.

17. The non-transitory computer-readable medium of claim 15, wherein:
each of the first plurality of offset values is not guaranteed to satisfy the error limit when the separation between the first word line and the one or more unprogrammed word lines is larger than the threshold; and
each of the second plurality of offset values is configured to satisfy the error limit when the separation between the first word line and the one or more unprogrammed word lines is smaller than or equal the threshold.

18. The non-transitory computer-readable medium of claim 12, wherein the instructions are further executable by the one or more processors to:
store, at the memory system, a table comprising a plurality of offset values that are each configured to satisfy the error limit associated with reading the second data both when a separation between the first word line and the one or more unprogrammed word lines is smaller than or equal to a threshold and when the separation between the first word line and the one or more unprogrammed word lines is larger than the threshold; and
select the offset value from the plurality of offset values.

19. The non-transitory computer-readable medium of claim 12, wherein the offset value is based at least in part on a position of a most recently written word line within the block.

20. The non-transitory computer-readable medium of claim 12, wherein:
the separation between the first word line and the one or more unprogrammed word lines being smaller than or equal to the threshold comprises the first word line being adjacent to an unprogrammed word line; and
the separation between the first word line and the one or more unprogrammed word lines being larger than the threshold comprises the first word line not being adjacent to any unprogrammed word line.

21. A method by a memory system, comprising:
writing first data to a first set of one or more word lines within a block of a memory array, wherein the block of the memory array comprises one or more unprogrammed word lines after writing the first data, each of the one or more unprogrammed word lines comprising a word line coupled with unprogrammed memory cells; and
reading, after writing the first data, second data from a first word line of the first set of one or more word lines using a read voltage that is based at least in part on an offset value, wherein the offset value is configured to satisfy an error limit associated with reading the second data both when a separation between the first word line and the one or more unprogrammed word lines is smaller than or equal to a threshold and when the separation between the first word line and the one or more unprogrammed word lines is larger than the threshold.

22. The method of claim 21, wherein the separation between the first word line and the one or more unprogrammed word lines is smaller than or equal to the threshold, the method further comprising:
reading third data from a second word line of the first set of one or more word lines using a second read voltage that is different than the read voltage, wherein a separation between the second word line and the one or more unprogrammed word lines is larger than the threshold, and wherein the second read voltage is based at least in part on a second offset value that is configured to satisfy the error limit when the separation between the second word line and the one or more unprogrammed word lines is larger than the threshold.

23. The method of claim 21, wherein the separation between the first word line and the one or more unprogrammed word lines is larger than the threshold, the method further comprising:
reading fourth data from a third word line of the first set of one or more word lines using a third read voltage that is different than the read voltage, wherein a separation between the third word line and the one or more unprogrammed word lines is smaller than or equal to the threshold, and wherein the third read voltage is based at least in part on a third offset value that is configured to satisfy the error limit when the separation between the third word line and the one or more unprogrammed word lines is smaller than or equal to the threshold.

24. The method of claim 21, further comprising:
storing, at the memory system, a first table of offset values and a second table of offset values, wherein:
the first table comprises a first plurality of offset values each associated with the separation between the first word line the one or more unprogrammed word lines being smaller than or equal to the threshold, and
the second table comprises a second plurality of offset values each associated with the separation between the first word line the one or more unprogrammed word lines being larger than the threshold; and
selecting the offset value from the first plurality of offset values or from the second plurality of offset values, wherein whether the offset value is selected from the first plurality of offset values or is selected from the second plurality of offset values is based at least in part on whether the separation between the first word line and the one or more unprogrammed word lines is larger than the threshold.

25. The method of claim 21, further comprising:
storing, at the memory system, a table comprising a plurality of offset values that are each configured to satisfy the error limit associated with reading the second data both when a separation between the first word line and the one or more unprogrammed word lines is smaller than or equal to a threshold and when the separation between the first word line and the one or more unprogrammed word lines is larger than the threshold; and
selecting the offset value from the plurality of offset values.
